(19) United States
(12) Patent Application Publication
(10) Pub. No.: US 2026/0169762 A1
(43) Pub. Date: Jun. 18, 2026

(54) ASYNCHRONOUS FINITE STATE MACHINE CIRCUIT, CORRESPONDING METHOD OF OPERATION AND INTEGRATED CIRCUIT

(71) Applicant: STMicroelectronics International N.V., Geneva (CH)

(72) Inventors: Francesco Battini, Milan (IT); Roberta Priolo, Milano (IT); Enea Dimroci, Borgo San Dalmazzo (IT)

(21) Appl. No.: 19/419,944

(22) Filed: Dec. 15, 2025

(30) Foreign Application Priority Data
Dec. 16, 2024 (IT) 102024000028611

(51) Int. Cl. G06F 9/448

(52) U.S. Cl. CPC G06F 9/4498

(57) ABSTRACT

An embodiment asynchronous finite state machine (AFSM) circuit includes a first state register configured to output a first state acknowledgment signal in response to the AFSM circuit transitioning to a first state, a second state register configured to output a second state acknowledgment signal in response to the AFSM circuit transitioning to a second state, a first acknowledgement branch configured to convey the second state acknowledgment signal from the second state register to the first state register, a second acknowledgement branch configured to convey the first state acknowledgment signal from the first state register to the second state register, and transition logic circuitry. The transition logic circuitry is configured to: interrupt the first acknowledgement branch in response to a first transition signal indicating a transition, of the AFSM circuit, from the first state to the second state; and interrupt the second acknowledgement branch in response to a second transition signal indicating a transition, of the AFSM circuit, from the second state to the first state.

### CROSS-REFERENCE TO RELATED APPLICATION

This application claims the benefit of Italian Patent Application Number 102024000028611, filed on Dec. 16, 2024, which application is hereby incorporated herein by reference.

### TECHNICAL FIELD

The description relates to finite state machines (FSMs).

Aspects of the present description can be used, for instance, in a variety of devices such as, merely by way of example, display drivers (DC-DC drivers for AMOLED display devices), power management integrated circuits (PMICs), rectifiers, preamplifiers for disk storage applications.

### BACKGROUND

The designation Finite State Machine (FSM), derived from a mathematical model of computation, applies to a machine that can be in one of a finite number of states at any given time and changes from one state to another, thus undergoing a so-called “transition”, in response to an input received.

A FSM is defined by a list of states starting from an initial state and by the inputs that trigger transitions between states. FSM behavior underlies operation of many devices configured to perform a predetermined sequence of actions based on a sequence of events. For example, a FSM can be implemented in the form of an electrical circuit. A computer or controller may be exemplary of such a circuit.

While used in its simplest form for brevity, throughout this description the designation “FSM circuit” or “FSM” is intended to refer to “an electrical circuit implementing the FSM model”.

A computer or controller may be used to implement such an FSM circuit. A main motivation of using digital circuitry operating according to an FSM paradigm (in short, an FSM circuit) lies in the inherent high complexity of corresponding analog circuitry.

### SUMMARY

In an asynchronous finite state machine (AFSM) state transition, an occurrence of a double state loop may lead to a deadlock of the AFSM. The deadlock risk is caused by the fact that each state is both the source and the destination of the other and the destination state could be deactivated while being set.

Such a technical difficulty can be addressed by inserting a dummy state to break the double state loop. However, this results in undesired area overhead and delay of an extra state and arc. Testing time is increased and pattern computation is more complex.

Embodiments of the present disclosure contribute in addressing the issues discussed above.

An embodiment provides an asynchronous finite state machine (AFSM) comprising: a first state register configured to output a first state acknowledgment signal in response to the AFSM circuit transitioning to a first state, a second state register configured to output a second state acknowledgment signal in response to the AFSM circuit transitioning to a second state, a first acknowledgement branch configured to convey the second state acknowledgment signal from the second state register to the first state register, a second acknowledgement branch configured to convey the first state acknowledgment signal from the first state register to the second state register, transition logic circuitry configured to:
interrupt the first acknowledgement branch in response to a first transition signal indicating a transition, of the AFSM circuit, from the first state to the second state, and interrupt the second acknowledgement branch in response to a second transition signal indicating a transition, of the AFSM circuit, from the second state to the first state.

According to an embodiment, the first acknowledgement branch comprises a first AND gate that is configured to receive, as inputs, the first transition signal and the second state acknowledgment signal and having an output coupled to the first state register, and the second acknowledgement branch comprises a second AND gate that is configured to receive, as inputs, the second transition signal and the first state acknowledgment signal and having an output coupled to the second state register.

According to an embodiment, the first state register and the second state register comprise: a first input port, a second input port, an output port, a digital buffer having an input terminal coupled to the first input port and an output terminal, a state register AND gate having an input terminal coupled to the output terminal of the digital buffer, an input terminal coupled to the output terminal, and an output terminal, a state register OR gate having an input terminal coupled to the output terminal of the state register AND gate, an input terminal coupled the second input port.

According to an embodiment, the transition logic circuitry comprises: a first transition signal generator configured to condition issuing the first transition signal in response to the second transition signal being de-asserted and the first state acknowledgment signal being asserted, and a second transition signal generator configured to condition issuing the second transition signal in response to the first transition signal being de-asserted and the second state acknowledgment signal being asserted.

According to an embodiment, the first transition signal generator comprises a first transition signal AND gate configured to be traversed by said first transition signal in response to the second transition signal being de-asserted and the first state acknowledgment signal being asserted, and the second transition signal generator comprises a second transition signal AND gate configured to be traversed by said second transition signal in response to the first transition signal being de-asserted and the second state acknowledgment signal being asserted.

According to an embodiment, the first transition signal generator comprises a first transition signal NOR gate receiving, as inputs, a negated replica of the second transition signal and the first state acknowledgment signal, and the second transition signal generator comprises a second transition signal NOR gate receiving, as inputs, a negated replica of the first transition signal and the second state acknowledgment signal.

According to an embodiment, the circuit comprises one or more further states that each have a respective further state register, a further transition signal generator, and a further acknowledgment branch, wherein the transition logic circuitry is configured to: detect at least one further transition signal indicative of a transition of the AFSM circuit from a state of said plurality of states to the further state, and interrupt the further acknowledgment branch in response to detecting said at least one further transition signal, and wherein each acknowledgment branch comprises a respective AND gate receiving as inputs a state acknowledgment signal outputted by a respective state register and a corresponding transition signal.

According to an embodiment, the first input port of each state register is coupled to an OR gate receiving, as input, signals originating from the AND gates of respective acknowledgment branches, the second input port of each state register is coupled to an OR gate receiving, as input, transition signals associated to states from which the AFSM circuit is configured to transition, and the output port of each state register is coupled to an inverting input of a NOR gate, the NOR gate further receiving, as input, transition signals associated to states from which the AFSM circuit is configured to transition, and having an output terminal coupled to an input terminal of the respective transition signal generator.

A embodiment provides a method of operating an asynchronous finite state machine (AFSM) circuit, the method comprising: outputting, from a first state register, a first state acknowledgment signal in response to the AFSM circuit transitioning to the first state, outputting, from a second state register, a second state acknowledgment signal in response to the AFSM circuit transitioning to the second state, configuring a first acknowledgement branch to convey the second state acknowledgment signal from the second state register to the first state register, configuring a second acknowledgement branch to convey the first state acknowledgment signal from the first state register to the second state register, and interrupting the first acknowledgement branch in response to a first transition signal that indicates a transition of the AFSM circuit from the first state to the second state, and interrupting the second acknowledgement branch in response to a second transition signal that indicates a transition of the AFSM circuit from the second state to the first state.

According to an embodiment, the method further comprises: receiving, as inputs to a first AND gate of the first acknowledgement branch, the first transition signal and the second state acknowledgment signal, and outputting, from the first AND gate of the first acknowledgement branch, a signal that is issued, as an input, to the first state register.

According to an embodiment, the method further comprises: receiving, as inputs to a second AND gate of the second acknowledgement branch, the second transition signal and the first state acknowledgment signal, and outputting, from the second AND gate of the second acknowledgement branch, a signal that is issued, as an input, to the second state register.

According to an embodiment, the method further comprises: generating, by a first transition signal generator, the first transition signal in response to the second transition signal being de-asserted and the first state acknowledgment signal being asserted.

According to an embodiment, the method further comprises: generating, by a second transition signal generator, the second transition signal in response to the first transition signal being de-asserted and the second state acknowledgment signal being asserted.

An embodiment provides an integrated circuit implementing an asynchronous finite state machine (AFSM), the circuity comprising: a first state register configured to output a first state acknowledgment signal in response to the AFSM circuit transitioning to a first state, a second state register configured to output a second state acknowledgment signal in response to the AFSM circuit transitioning to a second state, a first acknowledgement branch configured to convey the second state acknowledgment signal from the second state register to the first state register, a second acknowledgement branch configured to convey the first state acknowledgment signal from the first state register to the second state register, and transition logic circuitry configured to: interrupt the first acknowledgement branch in response to a first transition signal indicating a transition, of the AFSM circuit, from the first state to the second state; and interrupt the second acknowledgement branch in response to a second transition signal indicating a transition, of the AFSM circuit, from the second state to the first state.

According to an embodiment, the first acknowledgement branch comprises a first AND gate that is configured to receive, as inputs, the first transition signal and the second state acknowledgment signal and having an output coupled to the first state register; and the second acknowledgement branch comprises a second AND gate that is configured to receive, as inputs, the second transition signal and the first state acknowledgment signal and having an output coupled to the second state register.

According to an embodiment, the first state register and the second state register comprise: a first input port, a second input port, an output port, a digital buffer having an input terminal coupled to the first input port and an output terminal, a state register AND gate having an input terminal coupled to the output terminal of the digital buffer, an input terminal coupled to the output terminal, and an output terminal, and a state register OR gate having an input terminal coupled to the output terminal of the state register AND gate, an input terminal coupled the second input port.

According to an embodiment, the transition logic circuitry comprises: a first transition signal generator configured to condition issuing the first transition signal in response to the second transition signal being de-asserted and the first state acknowledgment signal being asserted, and a second transition signal generator configured to condition issuing the second transition signal in response to the first transition signal being de-asserted and the second state acknowledgment signal being asserted.

According to an embodiment, the first transition signal generator comprises a first transition signal AND gate configured to be traversed by said first transition signal in response to the second transition signal being de-asserted and the first state acknowledgment signal being asserted, and the second transition signal generator comprises a second transition signal AND gate configured to be traversed by said second transition signal in response to the first transition signal being de-asserted and the second state acknowledgment signal being asserted.

According to an embodiment, the first transition signal generator comprises a first transition signal NOR gate receiving, as inputs, a negated replica of the second transition signal and the first state acknowledgment signal, and the second transition signal generator comprises a second transition signal NOR gate receiving, as inputs, a negated replica of the first transition signal and the second state acknowledgment signal.

According to an embodiment, the circuit comprises one or more further states that each have a respective further state register, a further transition signal generator, and a further acknowledgment branch, wherein the transition logic circuitry is configured to: detect at least one further transition signal indicative of a transition of the AFSM circuit from a state of said plurality of states to the further state, and interrupt the further acknowledgment branch in response to detecting said at least one further transition signal, and wherein each acknowledgment branch comprises a respective AND gate receiving as inputs a state acknowledgment signal outputted by a respective state register and a corresponding transition signal.

One or more embodiments relate to a corresponding method of operating such AFSM circuit. A power management integrated circuit (PMIC), a rectifier, a preamplifier for disk storage may be non-limiting examples of such a circuit. Solutions as described herein overcome a deadlock hazard inherent in double state loops in AFSMs by modifying the transition implementation.

In fact, during a transition from a first state to a second state, an acknowledgement of the transition may be incorrectly triggered that should be raised only after a transition from the second state to the first state. In solutions as described herein each acknowledgement path is enabled only during the corresponding transition and is masked when not triggered.

In that way a race condition is countered and an undesired acknowledgement arc cannot be taken. Advantageously, this result can be obtained by adding two AND gates in the core logic of an AFSM.

### BRIEF DESCRIPTION OF THE DRAWINGS

One or more embodiments will now be described, by way of example only, with reference to the annexed figures, wherein:

FIG. 1 is a block diagram providing an elementary representation of an FSM circuit.

FIG. 2 is illustrative of operation of an FSM circuit as illustrated in FIG. 1.

FIG. 3A is an example of an FSM circuit.

FIG. 3B is an example of a portion an FSM circuit implementation.

FIG. 4 is an example of a an FSM circuit, in accordance with an embodiment.

FIG. 5 is illustrative of operation of an FSM circuit including the features illustrated in FIG. 3A and FIG. 4; and

FIG. 6 is an example of features of an AFSM circuit operating as illustrated in FIG. 5.

The figures are drawn to clearly illustrate the relevant aspects of the embodiments and are not necessarily drawn to scale.

The edges of features drawn in the figures do not necessarily indicate the termination of the extent of the feature.

### DETAILED DESCRIPTION OF ILLUSTRATIVE EMBODIMENTS

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is included in at least one embodiment. Hence, phrases such as “in an embodiment” or “in one embodiment” that may be present in one or more points of the present description do not necessarily refer to one and the same embodiment. Moreover, particular configurations, structures, or characteristics may be combined in any adequate way in one or more embodiments.

The headings/references used herein are provided merely for convenience and hence do not define the extent of protection or the scope of the embodiments.

Throughout the figures annexed herein, unless the context indicates otherwise, like parts or elements are indicated with like references/numerals and a corresponding description will not be repeated for the sake of brevity.

Once more, for the sake of simplicity and ease of explanation:
a same designation may be applied throughout this description to designate a certain node or line as well as a signal occurring at that node or line;
a same designation may be applied throughout this description to designate certain component (such as a capacitor, resistor or inductor of coil) as well as electrical parameters thereof;
as used herein, the designation Finite State Machine, FSM circuit (in short, FSM) is intended to indicate “an electrical circuit implementing an FSM model”.

Also, when it is mentioned that an element is “connected to” or “coupled to” another element, it should be understood that still another element may be interposed therebetween, as well as that the element may be connected or coupled directly to another element. For example, in the following description, reference will be made to a circuit F1 coupled to a state register SR2 via an OR gate 222, that is with the gate 222 intermediate the circuit F1 coupled to the state register SR2.

On the contrary, in some instances when it is mentioned that an element is “connected directly to” or “coupled directly to” another element, it should be understood that still another element is not interposed therebetween.

An underlying concepted related to a FSMs is to store a sequence of different states and transitions between them depending on the values of the inputs and the current state of the machine.

An FSM can be of two types. The first type of FSM may be, for example, a Moore type, where the output of the state machine is purely dependent on the state variables. The second type of FSM may be, for example, a Mealy type, where the output can depend on the current state variable values and the input values.

The procedure for designing an electrical circuit implementing a FSM involves steps such as: identifying inputs and outputs, defining a state transition diagram; writing a state transition table and an output table (for a Moore machine) or a combined state transition and output table (for a Mealy machine), selecting state encodings, with selection affecting the hardware design, writing Boolean equations for the next state and output logic, and devising a corresponding circuit diagram.

As noted, FSM circuits can be described by mathematical models.

These can be implemented as asynchronous FSMs, as Moore machines where the outputs are purely dependent on the active state.

The concept of arc cells may be described with reference to a FSM. It is noted that an “arc”, as repeatedly mentioned herein, is oftentimes referred to an “edge” of a graph, in so far as an FSM can be described by a graph.

For instance, document US 2024/176384 A1 describes an AFSM core that includes a destination state-cell generating a destination state-signal, and a source state-cell generating a source state-signal and causing transition of the source state-signal in response to an acknowledgement indicating transition of the destination state-signal. The acknowledgment is communicated through a delay. A state-overlap occurs between transition of the destination state-signal and transition of the source state-signal. An output-net includes a balanced logic-tree receiving inputs, including the destination state-signal, from the core, and an additional logic-tree cascaded with the balanced logic-tree to form an unbalanced logic-tree so an input to the additional logic-tree is provided by output from the balanced logic-tree and another input receives the source state-signal. Tree propagation time occurs between receipt of a transition in the destination state-signal by the balanced logic-tree and a resulting transition of the output from the balanced logic-tree. The delay circuit causes the state-overlap to exceed the tree propagation time.

Document US 2018/246819 A1 describes a sequential asynchronous system and a method for operating the same. The method includes operating a first asynchronous finite state machine (AFSM) at a first clock rate and operating a second asynchronous finite state machine at a second clock rate. The method also includes generating, with fork logic, a fork request based on a first state of the first asynchronous finite state machine and receiving, with join logic, the fork request from the fork logic. The method further includes receiving, with the join logic, a communication request from the second asynchronous finite state machine based on a second state of the second asynchronous finite state machine and initiating, with the join logic, a state transition of the second asynchronous finite state machine. The method also includes providing, with the join logic, a join acknowledgement to the fork logic upon completion of the state transition.

Solutions as described herein facilitate saving area and delay as associated to an extra state and arc. Testing time and testing pattern computation are correspondingly reduced, without inserting a dummy state in the state loop.

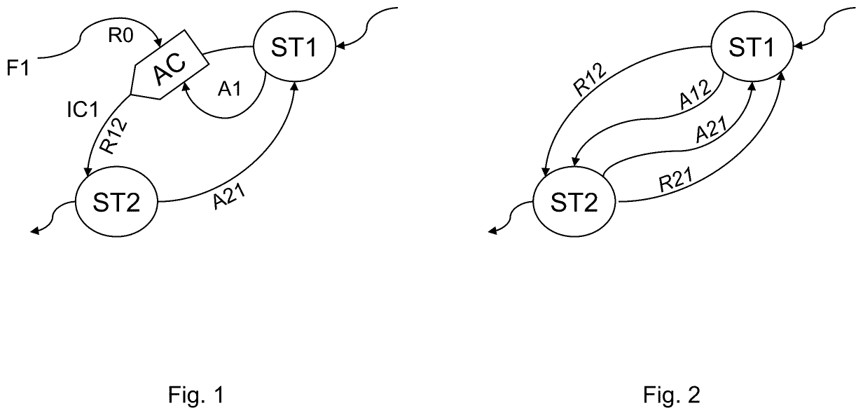

The states in an FSM (circuit) can be represented by nodes such as ST1 and ST2 in FIG. 1.

A representation of an FSM including two states/nodes is reproduced in FIG. 1 for simplicity and ease of explanation. However, the present disclosure is not limited to FSM's having two states/nodes and, instead, the FSM of the present disclosure can include any number (including very large numbers) of states/nodes.

FIG. 1 represents, by way of non-limiting example, a handshake i.e., the process that kicks off a communication, between two states ST1 and ST2 in an asynchronous FSM (AFSM, in short).

Arc cells AC are used to represent the inter-state transitions that take place based on request signals, indicated as R12 or R21, and acknowledgement signals, indicated as A12 or A21.

Specifically, for the sake of clarity, the request signals are labelled hereinafter with the prefix ‘R’ followed by the source state number, and by the destination state number. Accordingly, the acknowledgment signals are labelled with the suffix ‘A’ followed by the source state number, and by the destination state number.

For instance, in FIG. 1 is illustrated a request signal R12 indicating a transition request originating from state ST1 and having as destination state the state ST2. Accordingly, the state ST2 receives the transition request R12 and, in response to the FSM circuit successfully transitioning from state ST1 to state ST2, the state ST2 generates an acknowledgment signal A21, which is received by state ST1.

In asynchronous finite state machines (AFSMs) transitions are based on a handshake protocol of request - acknowledgement. If a state ST1 is active and the condition F1 on the arc AC is triggered, a request R12 is sent to the arc cell AC, then it is passed to the state cell ST2. After the request R12 is received by the destination state i.e., ST2, the acknowledgement A21 is sent back to the source state ST1 to deactivate it. Then, an acknowledgement A1 is sent to deactivate the arc cell.

This kind of operation is exemplified in FIG. 1.

A corresponding exemplary protocol description may be as follows:
F1−>IC1 request to arc i.e., a request signal R0 is sent to the arc cell AC;
IC1−>ST2 request to state i.e., the request signal R12 is forwarded to the state ST2;
ST2−>ST1 acknowledgment to state i.e., an acknowledgement signal A21 is sent to the state ST1; and
ST1−>IC1 acknowledgment to arc i.e., an acknowledgement signal A1 is forwarded from the state ST1 to the arc cell AC.

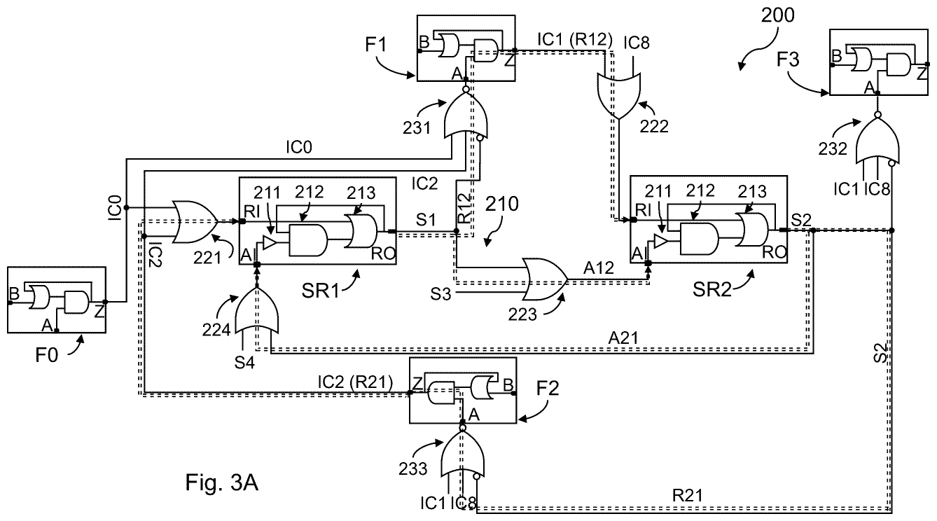

In a current implementation of an AFSM state transition, implementing a double state loop could lead to a deadlock of the AFSM. The deadlock hazard is caused by the fact that each state is both the source and the destination of the other and the destination state could be deactivated while being set, as portrayed in FIG. 2.

This situation may be related to various factors.

For instance, when a transition is triggered from state ST1 to state ST2, a ‘1’ logic value is propagated from the state ST1 through the request path R12 to activate the arc F1 and the state ST2; nevertheless, at the same time a ‘1’ logic value is propagated also to the acknowledgement path A12 from the state ST1 to the state ST2, so that the state ST2 is deactivated.

Also, when in the state ST1, in response to a condition F1 being raised, the arc R12 goes to ‘1’; the state ST2 is activated and at the same time, since state ST1 also represents a destination for state ST2, an acknowledgement A12 is triggered on the state ST2 in order to deactivate it. This is a critical condition in so far as the state ST2 is kept active only by the acknowledgement signal A12.

Accordingly, in response to a transition being triggered while being in state ST2, a ‘1’ logic value is propagated from state ST2 to state ST1 through the request path R21. At the same time, since state ST2 is also a destination state for state ST1, an acknowledgment A21 is triggered on the state ST1 in order to deactivate it.

In both FIG. 1 and FIG. 2 unreferenced lines and arrows are shown entering/exiting the states ST1, ST2 to generally indicate possible interaction of other FSM states with these two states. In fact, the one provided in FIG. 1 and FIG. 2 is “nutshell” representation of an FSM that can include any number of states/nodes: the states ST3, ST4, and ST8 referred to in the following are exemplary of such other states.

A known solution to the technical difficulty outlined in the foregoing involves inserting a dummy state to break the double state loop. This results in undesired area overhead and delay of an extra state and arc to go back to the state ST1. Testing time is increased and pattern computation is made more complex.

As noted, during the transition IC1 from the state ST1 to the state ST2, the acknowledgement of the transition IC2 is incorrectly triggered while it should be raised only after the transition IC2 from ST2 to ST1.

In solutions as described herein, each acknowledgement path is enabled only during a corresponding transition and is masked when not triggered. In such a way, a race condition is countered in so far as an undesired acknowledgement arc cannot be taken.

This can be implemented by adding two AND gates in the core logic of the AFSM e.g., the transition logic, as shown in the following.

Concerning the implementation, the core logic of an AFSM machine typically comprises a state register comprising two or more states, one or more transition logic circuits, one or more input logic circuits for processing input signals before being fed to the transition logic circuits, and one or more output logic circuits for generating output signals based on the current state of the AFSM machine and, optionally, the input signals.

In particular, in a two-state AFSM implementing a double state loop, a state register can be implemented by assigning to each state e.g., ST1 and ST2, a single bit that can be stored in a flip-flop or a latch.

The transition logic circuitry implements the arc transitions of an AFSM machine, and is configured to implement the state transition function of the AFSM, taking the current state and input signals as inputs and producing the next state as output.

Typically, the transition logic circuits comprise combinational circuits that determine the next state based on the current state and inputs. Such a circuitry can be implemented by using combinational logic gates such as AND, OR, and NOT gates. The transition logic is often derived from Boolean expressions or truth tables that define the overall behavior of the AFSM machine, wherein each bit of the next state is typically expressed as a function of the current state bits and input variables. The outputs of the transition logic feed directly into the inputs of the state registers (flip-flops), thus allowing state changes in the AFSM.

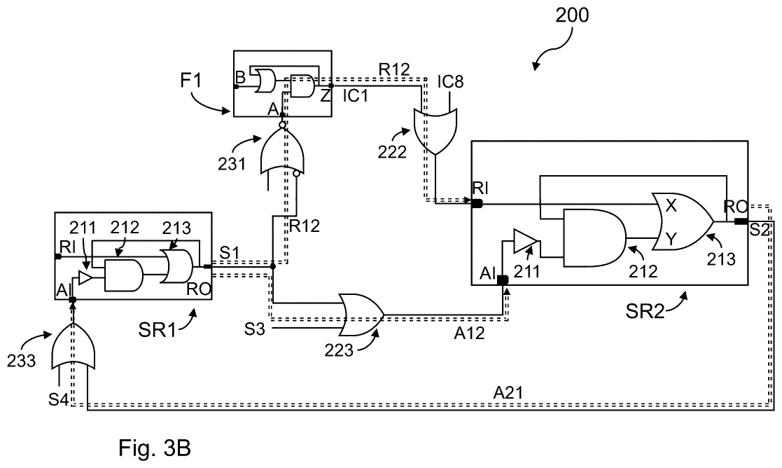

In this regard, FIG. 3A is an example of a circuit implementation of a double state loop without any “fix” as proposed herein.

As illustrated, such implementation of a double state loop comprises a first state register SR1 and a second state register SR2, respectively implementing the states ST1 and ST2 of the exemplary AFSM discussed in the foregoing.

In particular, the first state register SR1 and the second state register SR2 comprise a first input terminal AI (Acknowledgment In), a second input terminal RI (Request In), and an output terminal RO (Request Out). Each state register SR1, SR2 comprises a digital buffer 211 having an input terminal coupled to the first input terminal AI and an output terminal coupled to an input terminal of a state register AND gate 212.

In turn, the state register AND gate 212 has a further input terminal coupled to the output terminal RO, and has an output terminal coupled to an input terminal of a state register OR gate 213.

The state register OR gate 213 has a further input terminal coupled to the second input terminal RI of the state registers SR1, SR2, and has an output terminal coupled to the output terminal RO.

In various embodiments, each state register SR1, SR2 is configured to produce as output a respective state acknowledgement signal in response to successfully performing a state transition. For example, the first state register SR1 outputs a first state acknowledgement signal S1 in response to a transition from state ST2 to ST1, whereas the second state register SR2 output a second state acknowledgement signal S2 in response to a transition from state ST1 to ST2.

It shall be noted that such circuital implementations of state registers, as the state registers SR1 and SR2 described herein, are provided merely as example, and that different implementations for the state registers are possible.

In addition to the state registers, an AFSM comprises a plurality of logic circuits implementing the arc transitions, in general referred to as transition logic circuitry 210. With reference to the example of FIG. 3A, four transition logic circuits are present including, e.g., a first transition logic circuit F1, a second transition logic circuit F2, a third transition logic circuit F0, and a fourth transition logic circuit F3.

In various embodiments, the transition logic circuitry 210 can also comprise further circuits such as, for example, combinational circuits like AND gates or NOR gates, as it will be better detailed in the following of the disclosure.

Each transition logic circuit F0, F1, F2, and F3 comprise a first input terminal B, a second input terminal A, and an output terminal Z. Such transition logic circuits are represented as including an OR gate having an input terminal coupled to the first input terminal B, a further input terminal coupled to the output terminal Z, and an output terminal coupled to an input terminal of an AND gate, which has a further input terminal coupled to the second input terminal A, and an output terminal coupled to the output terminal Z of the respective transition logic circuit.

It is observed that such implementations of transition logic circuits such as, for example, the transition logic circuits F0, F1, F2, and F3, are merely provided by way of example, therefore the logic circuitry comprised in each transition logic circuit may differ, even substantially, from the examples provided depending on the application targeted such as, for example, on the desired state transitions to be implemented.

In particular, the first transition logic circuit F1 produces as output, at the respective output terminal Z, a first transition signal IC1. In a similar way, the second transition logic circuit F2 outputs a second transition signal IC2, whereas the third transition logic circuit F0 outputs a third transition signal IC0.

Transition logic circuits F0 and F3 are illustrated here essentially to once more highlight that a FSM can include any number (including very large numbers) of states/nodes.

For simplicity and ease of explanation, the following discussion will primarily focus on the states referred to hereinafter as first state ST1 and second state ST2, and on associated circuitry including the transition logic circuits, also referred to as transition signal generators F1 and F2.

The AFSM circuit pictured in FIG. 3A further comprises a first OR gate 221, a second OR gate 222, a third OR gate 223, and a fourth OR gate 224, plus a first NOR gate 231, a second NOR gate 232, and a third NOR gate 233.

The first OR gate 221 receives as input, at respective input terminals, the third transition signal IC0 produced as output by the third transition logic circuit F0, and the second transition signal IC2 produced as output by the second transition logic circuit F2. Based on the input signals IC0 and IC2, the first OR gate 221 performs a logical OR operation, and outputs the corresponding result to the second input terminal RI of the first state register SR1.

The second OR gate 222 receives as input, at respective input terminals, the first transition signal IC1 produced as output by the first transition logic circuit F1, and a further transition signal IC8. Based on the input signals IC1 and IC8, the second OR gate 222 performs a logical OR operations, and outputs the corresponding result to the second input terminal RI of the second state register SR2.

The further transition signal IC8 is intended to provide a realistic view of an AFSM as discussed herein. In addition to the states and arcs specifically considered so far for ease of explanation, FIG. 3A also makes reference to an implementation where other elements communicate with the state registers SR1 and SR2.

In fact, an FSM can include any number of states/nodes in addition to the states ST1, ST2 referred to primarily for the sake of simplicity and ease of explanation.

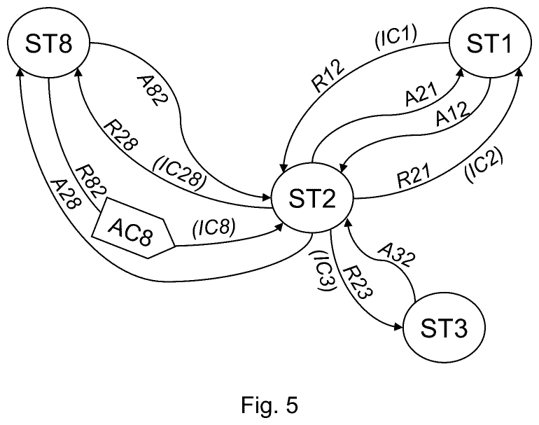

For example, FIG. 5 shows an example of a presence of another source state to ST2, here designated ST8, that forwards towards the state ST2 a signal IC8 over an arc, designated AC8.

Similarly, the third OR gate 223 receives as input, at respective input terminals, the first state acknowledgement signal S1 produced as output by the first state register SR1, and a further state acknowledgement signal S3, being outputted by a respective state register SR3. Based on the input signals S1 and S3, the third OR gate 223 performs a logical OR operation, and outputs the corresponding result to the first input terminal AI of the second state register SR2.

The designation S3 indicates another state acknowledgement signal from a state ST3, which is an example of a destination state from the state ST2. The signal S3 thus represents another acknowledgement signal, in addition to S1, that circles back to reset S2.

Finally, the fourth OR gate 224 receives as input, at respective input terminals, the second state acknowledgement signal S2 produced as output by the second state register SR2, and a further state acknowledgement signal S4, being outputted by a respective state register SR4. Based on the input signals S2 and S4, the fourth OR gate 224 performs a logical OR operations, and outputs the corresponding result to the first input terminal AI of the first state register SR1.

Accordingly, the first NOR gate 231 receives as input, at respective input terminals, the third transition signal IC0, and the second transition signal IC2, plus the first state acknowledgement signal S1 which is received at an inverting input terminal. On the basis of such input signals, the first NOR gate 231 returns as output the result of a NOR operation at a respective output terminal coupled to the second input terminal A of the first transition logic circuit F1.

Similarly, the second NOR gate 232 receives as input, at respective input terminals, the first transition signal IC1, and the transition signal IC8, plus the second state acknowledgement signal S2 which is received at an inverting input terminal. On the basis of such input signals, the second NOR gate 232 returns as output the result of a NOR operation at a respective output terminal coupled to the second input terminal A of the fourth transition logic circuit F3.

Finally, the third NOR gate 233 receives as input, at respective input terminals, the first transition signal IC1, and the transition signal IC8, plus the second state acknowledgement signal S2 which is received at an inverting input terminal. On the basis of such input signals, the third NOR gate 233 returns as output the result of a NOR operation at a respective output terminal coupled to the second input terminal A of the second transition logic circuit F2.

Substantially, when a transition is triggered from state ST1 to state ST2, a logic ‘1’ value is propagated from the state register SR1 through a request path R12, conveying the signal IC1, in order to activate the arc F1 and the state ST2. Nevertheless, at the same time the logic ‘1’ value is propagated also to the acknowledgement path A12, conveying the state acknowledgment signal S2, from state ST1 to state ST2, thus deactivating state ST2, in a fashion similar to the previous examples of FIG. 1 and FIG. 2.

As better detailed in FIG. 3B, if the AFSM circuit 200 finds itself in the state ST1, whenever the condition F1, implemented through the respective transition logic circuit F1, is raised, the arc IC1 goes to 1, and the state ST2 is consequently activated.

Contemporarily, the transition signal IC1 is triggered on the first input terminal AI of the second state register SR2, since the state register SR1 is also a destination of the state register SR2. In such a way, the ST2 state is kept active only by the transition signal IC1.

However, the second state register SR2 subsequently outputs the state acknowledgment signal S2, which is transmitted through the acknowledgment path A21 to reset the source state ST1. In such a way, a logic ‘0’ value is propagated through two parallel paths, causing the aforementioned race condition.

Furthermore, as pictured in FIG. 3B, the state acknowledgement signal S1 resets the source state ST1 and a ‘0’ logic value is propagated in parallel through two paths: the request path R12 deactivates the input of the state ST2, embodied by the corresponding state register SR2, and the acknowledgment path A12 deactivates the acknowledgement on the state ST2, thus causing a race condition.

Two exemplary scenarios may result: in case the R12 path is faster, the state ST2 is deactivated, thus creating a deadlock condition, as the node X of the state register OR gate 213 goes to ‘0’ before the node Y rises; or in case the A12 path is faster, the node Y goes to ‘1’ before the node X falls. Therefore, the node X goes to ‘0’ after the state ST2 has been latched, the state value is stable to ‘1’ and there is no deadlock.

In fact, if the path of the transition signal IC1 i.e., the request path R12, is faster than the path of the state acknowledgment signal S1 i.e., the acknowledgment path A12, the second state register SR2 suffers from an undesired deactivation, thus causing the deadlock of the AFSM circuit.

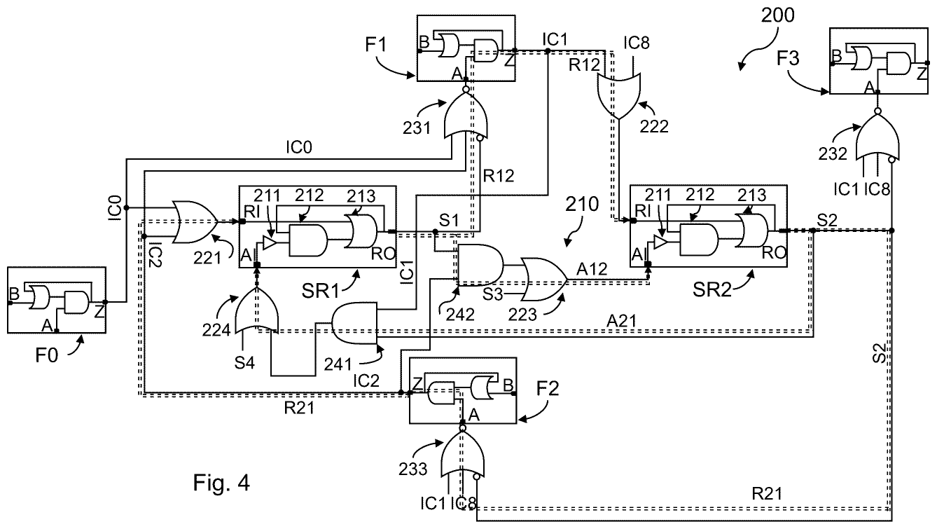

In this regard, a circuit arrangement capable of overcoming such an issue is illustrated in FIG. 4.

FIG. 4 is an example of a circuit implementation of a double state loop according to solutions as proposed herein, namely with an AND gate added on each acknowledgement branch with a corresponding transition signal as the input.

FIG. 4 is drawn by direct reference to FIG. 3A. Specifically, in FIG. 4 parts or elements like parts or elements already introduced in connection with FIG. 3A are indicated with like references/numerals and a corresponding description will not be repeated for FIG. 4 for the sake of brevity.

As illustrated, the circuit arrangement of FIG. 4 features the addition of a first AND gate 241, and of a second AND gate 242.

In particular, the first AND gate 241 has an input terminal coupled to the second state acknowledgment signal S2, outputted by the second state register SR2, and an input terminal coupled to the first transition signal IC1, which is outputted by the first transition logic circuit F1. On the basis of such input signals, the first AND gate 241 outputs the result of a logic AND operation at a respective input terminal, which is coupled to an input terminal of the fourth OR gate 224.

The second AND gate 242 has an input terminal coupled to the second transition signal IC2, outputted by the second transition logic circuit F2, and an input terminal coupled to the first state acknowledgment signal S1, outputted by the first state register SR1. As a result of a logic AND operation, the second AND gate 242 outputs at an output terminal coupled to an input terminal of the third OR gate 223.

Substantially, such an implementation of a double state loop involves adding an AND gate on each acknowledgement branch such as, e.g., A12 and A21, receiving the corresponding transition signals and state acknowledgment signals as input. In fact, as illustrated, the first AND 241 gate is placed along the first acknowledgment branch A21, and receives as input the transition signal IC1 and the state acknowledgment signal S2, whereas the second AND gate 242 is placed along the second acknowledgment branch A12, and receives as input the transition signal IC2 and the state acknowledgment signal S1.

In general, each AND gate placed along an acknowledgment signal detects whether a transition from a first state to a second state is ongoing and, in response to verifying that the AFSM circuit 200 is in the first state, allows the propagation of the acknowledgment signal along the acknowledgment path, thus effectively countering dead lock conditions.

As visible in FIG. 4, in response to an assertion of the first transition signal IC1, the second transition signal is equal to zero, IC2=0, and the acknowledgement branch A12 that was activated by S1 is interrupted while, on the other hand, IC1 is allowing propagation over the acknowledgment branch A21, that will be taken after the state ST2 is activated.

The same applies to the branch A12. In fact, in response to an assertion of the second transition signal IC2, the first transition signal gets equal to zero, IC1=0, and the acknowledgement branch A21, that was activated by S2, is interrupted. On the other hand, IC2 allows propagation over the acknowledgement branch A12.

Such approach can be considered as safe, as IC1 and IC2 shall not be asserted before the other transition is completed. For instance, during IC1, IC2 can be asserted only if the arc F2 is activated. The arc F2 can be activated if S2=1 and IC1=0. Hence, IC1 and IC2 are mutually exclusive. Moreover, IC1 remains active until the state ST1 is deactivated.

FIG. 5, already repeatedly referred to in the foregoing, is an example of a presence in an FSM such as an AFSM of any number of states/nodes as represented—merely by way of example—by nodes ST3 and ST8 in addition to the nodes ST1 and ST2.

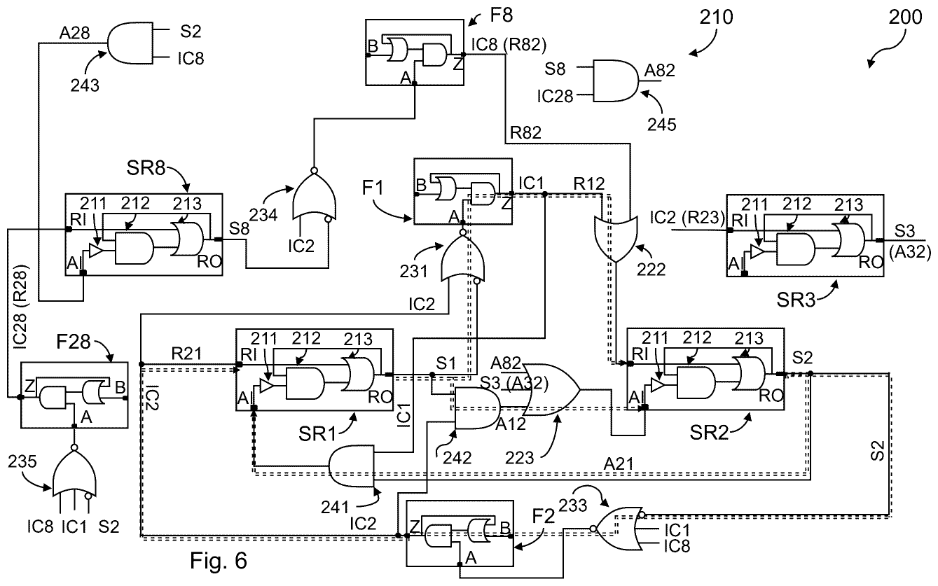

As illustrated, the request signal R12, originating form the first state ST1 and being received at the second state ST2, is also indicated using the reference of the corresponding state transition signal IC1, and accordingly the request signal R21 is also indicated using the reference of the corresponding state transition signal IC2, in order to ease understanding of corresponding circuital implementations such as the one proposed in FIG. 6, that will be described in the following.

As illustrated, the AFSM circuit is configured to implement further transitions from the states ST3 and ST8 to the state ST2. In particular, a request R23, indicated with a reference corresponding to a respective state transition signal IC3, originates from the state ST2 and is received by the state ST3, a request R28, also indicated as a transition signal IC28, originates from the state ST2 and is received by the state ST8, whereas a request R82, also indicated as a transition signal IC8, originates from the state ST8 and is received by the state ST2. Accordingly, an acknowledgment signal A32 is propagated from the state ST3 to the state ST2, an acknowledgment signal A82 is propagated from the state ST8 to the state ST2, and an acknowledgment A28 is generated at the state ST2 and is consequently received at the state ST8.

Of course, AFSM circuits comprising further states implemented in accordance with the solution described herein are possible, and can be obtained by adding further state registers and corresponding transition logic circuitry.

In this regard, FIG. 6 is illustrative of a portion of an embodiment of AFSM circuit 200 as described herein, comprising a further state ST8.

As pictured, the further state ST8 is implemented by means of a state register SR8, comprising a first input terminal AI, a second input terminal RI, and an output terminal RO, and corresponding transition generator circuits F28 and F8 being respectively configured to implement transitions from the further state ST8 to the second state ST2, and from the second state ST2 to the further state ST8.

In the example considered, an acknowledgment branch A28 conveys the state acknowledgment signal S2 originating from the state register SR2. Such acknowledgment branch A28, conveying the state acknowledgment signal S2, is interrupted by an AND gate 243 in response to detecting a de-asserted transition signal IC8.

For the sake of clarity, further transition generators described in the foregoing, such as the transition generators F0 and F3, are removed, along with the NOR gate 232 that is coupled thereto, whereas a further state register SR3, implementing the state ST3, is added. In particular, the state register SR3 is receiving, at a respective second input terminal RI, the signal IC2 indicating a request R23, which may originate from the second transition generator circuit F2 or from a further transition generator circuit implementing transitions from the second state ST2 to the third state ST3.

Consequently, as a transition to the state ST3 is performed, the third state register SR3 produces as output a third state acknowledgment signal S3, which is conveyed along a respective acknowledgment branch A32.

It is also noted that the third transition generator F3 is removed because, as pictured in FIG. 5, the state ST3 does not allow further transitions towards any state of the FSM circuit. Further, the third state acknowledgment signal S3 is received at the acknowledgment input terminal AI of the second state register SR2 through the OR gate 223, without being interrupted by a respective AND gate provided along the acknowledgment path, due to the fact that the inverse state transition such as, for example, the transition from state ST3 from ST2, is not implemented in the exemplary AFSM circuit 200 illustrated in FIGS. 5 and 6. In such a way, the circuit represented in FIG. 6 is illustrative of example of an implementation of the AFSM pictured in FIG. 5.

In general, the first input terminal AI of the state register SR8 can thus be configured to receive a plurality of acknowledgment branches, according to the number of states present in the AFSM circuit 200 from which transitioning from the considered state ST8 is possible. In such a way, each transition from one state to the considered state ST8 can be performed in accordance with the solution described herein, thus protecting the AFSM circuit 200 from undesired dead loop conditions.

In this regard, the outputs of each AND gate used for interrupting the acknowledgment branch, such as the AND gate 243 used in the acknowledgment branch A28, are fed as input to an OR gate having an output terminal coupled to the first input terminal AI of the state register ST8, in order to allow the AFSM circuit 200 to take into account all the possible transitions to the considered state ST8. An example of a state register receiving more than one acknowledgment branch can be seen in the state register SR2, which receives through the OR gate 223 the acknowledgment branches A12, A32, and A82, wherein the acknowledgment branch A32 is merely conveying the third state acknowledgment signal S3 without any AND gate interrupting the path, as the exemplary circuit 200 illustrated in FIG. 6, when in the third state ST3, does not allow any transition to further states.

The state register SR8 has its second input terminal RI configured to receive one or more transition signals, such as the second transition signal IC28 indicative of a transition from the second state ST2 to state ST8 as pictured in the example. In particular, each transition signal may be received at an OR gate, which outputs the result of a logical OR operation between the input signals to the second input terminal RI of the state register SR8, to which the OR gate is coupled, in a similar fashion to the OR gate 223 coupled to the state register SR2.

In general, such an OR gate receives input transition signals such as IC28, indicative of transitions of the AFSM circuit 200 from a state such as ST2 in the example considered, to the state ST8. Therefore, even if not pictured, the OR gate may receive further transition signals associated to transition from further states to the state ST8 considered herein.

As illustrated, the transition signal generator circuit F28 has an input terminal A coupled to an output terminal of an OR gate 235 receiving as input state transition signals corresponding to states from which transitioning to the second state ST2 is allowed, such as the first state transition signal IC1 and a further state transition signal IC8, along with the negated replica of the state acknowledgment signal corresponding to the state from which the FSM circuit 200 is transitioning, thus the state acknowledgment signal S2 in the example considered. The transition signal generator circuit F28 produces as output a state transition signal IC28, which is then received at the input terminal RI of the state register SR8, thus implementing a respective request branch R28.

Accordingly, as illustrated, the transition signal IC8 outputted by the transition signal generator F8 is received by OR gates coupled to other state registers, such as the OR gate 222 which is coupled to the first input terminal AI of the second state register SR2, in order to allow the AFSM circuit 200 to transition from the state ST8 to the state ST2 and thus conveying the request signal R82. Of course, further transitions from the state ST8 to other states can be implemented in a similar fashion, and are not illustrated in the example of FIG. 6 for the sake of simplicity and clarity.

The output terminal RO of the state register SR8 is coupled through a NOR gate 234 to the respective transition signal generator F8.

In particular, the NOR gate 234 receives as input the state transition signal IC2 from the second transition signal generator F2, and a state acknowledgment signal S8 from the output terminal RO state register SR8, which is received at an inverting input terminal.

The acknowledgment branch A82, conveying an acknowledgment signal indicative of a successful transition from state ST2 to ST8, is interrupted accordingly by means of the AND gate 245, whose output is received at the OR gate 223 having its output coupled to the AI terminal of the second state register SR2.

Accordingly, since the acknowledgment path A32 is not interrupted by an AND gate there along, the third state acknowledgment signal S3 is directly received as input by the OR gate 223.

Summarizing, the circuit arrangement described herein shows multiple different examples of implementing an AFSM circuit 200 comprising further states in accordance with the solution described herein. In such a way, when the AFSM circuit 200 transitions from a state such as, for instance, the first state ST1, or the second state ST2, to the further state ST8 described herein, the transition logic circuitry 210, in particular the AND gates 243, may interrupt the acknowledgment path A28 in response to detecting a de-asserted respective transition signal such as, for instance, the transition signal IC2 or the transition signal IC8.

In general, each input terminal A of each transition generator circuit e.g., F1 . . . F28, shall be coupled to a NOR gate e.g., 231 . . . 235, receiving as input a negated replica of the state acknowledgment signal representing the circuit current state e.g., S1 . . . S8, and one or more transition signals indicative of possible transitions to further states e.g., the NOR gate 233 receives the negated replica of the signal S2 and the transition signals IC1 and IC8, representing the possible transitions from state ST2 to states ST1 and ST8 in the FSM circuit 200.

Of course, further embodiments of the solution described herein comprising further states than the illustrated ones are possible. In particular, for each further state, the input port RI of a respective state register shall be coupled to an OR gate receiving as inputs the transition signals associated to states from which a transition is performed.

Accordingly, the input port AI of a respective state register shall be coupled to an OR gate receiving as inputs the acknowledgment paths A28 associated to states from which a transition is performed. As described in the foregoing, each acknowledgement path shall comprise an AND gate in accordance with the solution described herein, each AND gate receiving the acknowledgment path and a state transition signal originating from the state register to which the transition is directed to.

In other words, an AFSM circuit 200 may comprise one or more further states ST8 by having respective state registers SR8, transition signal generators F8 and F28, and acknowledgment branches A28 and A82. In such cases, the transition logic circuitry 210 is further configured to detect at least one further transition signal, such as the transition signals IC2 and IC28, indicative of a transition of the AFSM circuit 200 from a state of said plurality of states, such as the state ST2, to the further state ST8.

In response to detecting at least one further transition signal, such as the transition signal IC8, the transition logic circuitry 210 interrupts the further acknowledgment branch A28 in order to avoid the propagation of such acknowledgment.

Such interruption of the acknowledgment branch A28 is performed by means of a respective AND gate, such as the AND gates 243, receiving as inputs the state acknowledgment signal S2 outputted by the respective state register i.e., the state register SR2, and a corresponding transition signal e.g., the transition signal IC8.

In view of the above, the solutions described herein advantageously provide mitigations for deadlock hazard in double state loops in AFSMs by modifying the transition implementation. In fact, in previous implementations of the AFSM state transitions, if a double state loop is implemented, it could lead to a deadlock of the AFSM. The deadlock risk is caused by the fact that each state is both source and destination of the other state, hence the destination state could be deactivated while being set.

For instance, during a transition IC1 from the state ST1 to the state ST2, the acknowledgement of the transition IC2 is incorrectly triggered, whereas it should be raised only after a transition IC2 from the state ST2 to the state ST1.

By enabling each acknowledgement path only during the corresponding transition, and masking it when it is not triggered, the occurrence of such race condition is avoided, thus disabling the unwanted acknowledgement arc during each transition. Such a result can be obtained by advantageously adding two AND gates in the core logic of the AFSM.

Nonetheless, the solutions described herein advantageously allow saving of on-chip area and reduced delay times with respect to designs including an extra state and arc required for the insertion of a dummy state. Other advantages also include reduced testing time, and reduced testing pattern computation.

Without prejudice to the underlying principles, the details and embodiments may vary, even significantly, with respect to what has been described by way of example only, without departing from the extent of protection.

The extent of protection is determined by the annexed claims.

What is claimed is:

1. An asynchronous finite state machine (AFSM) circuit comprising:
a first state register configured to output a first state acknowledgment signal in response to the AFSM circuit transitioning to a first state;
a second state register configured to output a second state acknowledgment signal in response to the AFSM circuit transitioning to a second state;
a first acknowledgement branch configured to convey the second state acknowledgment signal from the second state register to the first state register;
a second acknowledgement branch configured to convey the first state acknowledgment signal from the first state register to the second state register; and
transition logic circuitry configured to:
interrupt the first acknowledgement branch in response to a first transition signal indicating a transition, of the AFSM circuit, from the first state to the second state; and
interrupt the second acknowledgement branch in response to a second transition signal indicating a transition, of the AFSM circuit, from the second state to the first state.

2. The AFSM circuit of claim 1, wherein:
the first acknowledgement branch comprises a first AND gate that is configured to receive, as inputs, the first transition signal and the second state acknowledgment signal and having an output coupled to the first state register; and
the second acknowledgement branch comprises a second AND gate that is configured to receive, as inputs, the second transition signal and the first state acknowledgment signal and having an output coupled to the second state register.

3. The AFSM circuit of claim 1, wherein the first state register and the second state register comprise:
a first input port,
a second input port,
an output port,
a digital buffer having an input terminal coupled to the first input port and an output terminal,
a state register AND gate having an input terminal coupled to the output terminal of the digital buffer, an input terminal coupled to the output terminal, and an output terminal, and
a state register OR gate having an input terminal coupled to the output terminal of the state register AND gate, an input terminal coupled the second input port.

4. The AFSM circuit of claim 3, wherein the transition logic circuitry comprises:
a first transition signal generator configured to condition issuing the first transition signal in response to the second transition signal being de-asserted and the first state acknowledgment signal being asserted; and
a second transition signal generator configured to condition issuing the second transition signal in response to the first transition signal being de-asserted and the second state acknowledgment signal being asserted.

5. The AFSM circuit of claim 4, wherein:
the first transition signal generator comprises a first transition signal AND gate configured to be traversed by said first transition signal in response to the second transition signal being de-asserted and the first state acknowledgment signal being asserted; and
the second transition signal generator comprises a second transition signal AND gate configured to be traversed by said second transition signal in response to the first transition signal being de-asserted and the second state acknowledgment signal being asserted.

6. The AFSM circuit of claim 4, wherein
the first transition signal generator comprises a first transition signal NOR gate receiving, as inputs, a negated replica of the second transition signal and the first state acknowledgment signal; and
the second transition signal generator comprises a second transition signal NOR gate receiving, as inputs, a negated replica of the first transition signal and the second state acknowledgment signal.

7. The AFSM circuit of claim 5, wherein the circuit comprises one or more further states that each have a respective further state register, a further transition signal generator, and a further acknowledgment branch, wherein the transition logic circuitry is configured to:
detect at least one further transition signal indicative of a transition of the AFSM circuit from a state of a plurality of states to the further state, and
interrupt the further acknowledgment branch in response to detecting said at least one further transition signal;
and wherein each acknowledgment branch comprises a respective AND gate receiving as inputs a state acknowledgment signal outputted by a respective state register and a corresponding transition signal.

8. The AFSM circuit of claim 7, wherein:
the first input port of each state register is coupled to an OR gate receiving, as input, signals originating from the AND gates of respective acknowledgment branches,
the second input port of each state register is coupled to an OR gate receiving, as input, transition signals associated to states from which the AFSM circuit is configured to transition, and
the output port of each state register is coupled to an inverting input of a NOR gate, the NOR gate further receiving, as input, transition signals associated to states from which the AFSM circuit is configured to transition, and having an output terminal coupled to an input terminal of the respective transition signal generator.

9. A method of operating an asynchronous finite state machine (AFSM) circuit, the method comprising:
outputting, from a first state register, a first state acknowledgment signal in response to the AFSM circuit transitioning to the first state;
outputting, from a second state register, a second state acknowledgment signal in response to the AFSM circuit transitioning to the second state;
configuring a first acknowledgement branch to convey the second state acknowledgment signal from the second state register to the first state register;
configuring a second acknowledgement branch to convey the first state acknowledgment signal from the first state register to the second state register; and
interrupting the first acknowledgement branch in response to a first transition signal that indicates a transition of the AFSM circuit from the first state to the second state; and
interrupting the second acknowledgement branch in response to a second transition signal that indicates a transition of the AFSM circuit from the second state to the first state.

10. The method of claim 9, the method further comprising:
receiving, as inputs to a first AND gate of the first acknowledgement branch, the first transition signal and the second state acknowledgment signal; and
outputting, from the first AND gate of the first acknowledgement branch, a signal that is issued, as an input, to the first state register.

11. The method of claim 1, the method further comprising:
receiving, as inputs to a second AND gate of the second acknowledgement branch, the second transition signal and the first state acknowledgment signal; and
outputting, from the second AND gate of the second acknowledgement branch, a signal that is issued, as an input, to the second state register.

12. The method of claim 1, the method further comprising:
generating, by a first transition signal generator, the first transition signal in response to the second transition signal being de-asserted and the first state acknowledgment signal being asserted.

13. The method of claim 1, the method further comprising:
generating, by a second transition signal generator, the second transition signal in response to the first transition signal being de-asserted and the second state acknowledgment signal being asserted.

14. An integrated circuit implementing an asynchronous finite state machine (AFSM), the circuity comprising:
a first state register configured to output a first state acknowledgment signal in response to the AFSM circuit transitioning to a first state;
a second state register configured to output a second state acknowledgment signal in response to the AFSM circuit transitioning to a second state;
a first acknowledgement branch configured to convey the second state acknowledgment signal from the second state register to the first state register;
a second acknowledgement branch configured to convey the first state acknowledgment signal from the first state register to the second state register; and
transition logic circuitry configured to:
interrupt the first acknowledgement branch in response to a first transition signal indicating a transition, of the AFSM circuit, from the first state to the second state; and
interrupt the second acknowledgement branch in response to a second transition signal indicating a transition, of the AFSM circuit, from the second state to the first state.

15. The integrated circuit of claim 14, wherein:
the first acknowledgement branch comprises a first AND gate that is configured to receive, as inputs, the first transition signal and the second state acknowledgment signal and having an output coupled to the first state register; and
the second acknowledgement branch comprises a second AND gate that is configured to receive, as inputs, the second transition signal and the first state acknowledgment signal and having an output coupled to the second state register.

16. The integrated circuit of claim 14, wherein the first state register and the second state register comprise:
a first input port,
a second input port,
an output port,
a digital buffer having an input terminal coupled to the first input port and an output terminal,
a state register AND gate having an input terminal coupled to the output terminal of the digital buffer, an input terminal coupled to the output terminal, and an output terminal, and
a state register OR gate having an input terminal coupled to the output terminal of the state register AND gate, an input terminal coupled the second input port.

17. The integrated circuit of claim 14, wherein the transition logic circuitry comprises:
a first transition signal generator configured to condition issuing the first transition signal in response to the second transition signal being de-asserted and the first state acknowledgment signal being asserted; and
a second transition signal generator configured to condition issuing the second transition signal in response to the first transition signal being de-asserted and the second state acknowledgment signal being asserted.

18. The integrated circuit of claim 17, wherein:
the first transition signal generator comprises a first transition signal AND gate configured to be traversed by said first transition signal in response to the second transition signal being de-asserted and the first state acknowledgment signal being asserted; and
the second transition signal generator comprises a second transition signal AND gate configured to be traversed by said second transition signal in response to the first transition signal being de-asserted and the second state acknowledgment signal being asserted.

19. The integrated circuit of claim 17, wherein:
the first transition signal generator comprises a first transition signal NOR gate receiving, as inputs, a negated replica of the second transition signal and the first state acknowledgment signal; and
the second transition signal generator comprises a second transition signal NOR gate receiving, as inputs, a negated replica of the first transition signal and the second state acknowledgment signal.

20. The integrated circuit of claim 18, wherein the circuit comprises one or more further states that each have a respective further state register, a further transition signal generator, and a further acknowledgment branch, wherein the transition logic circuitry is configured to:
detect at least one further transition signal indicative of a transition of the AFSM circuit from a state of a plurality of states to the further state, and
interrupt the further acknowledgment branch in response to detecting said at least one further transition signal;
and wherein each acknowledgment branch comprises a respective AND gate receiving as inputs a state acknowledgment signal outputted by a respective state register and a corresponding transition signal.
